(19) United States
(12) Patent Application Publication
(10) Pub. No.: US 2023/0231538 A1
(43) Pub. Date: Jul. 20, 2023

(54) MEMS RESONATOR AND MANUFACTURING METHOD

(71) Applicant: KYOCERA Tikitin Oy, Espoo (FI)

(72) Inventor: Aarne OJA, Espoo (FI)

(73) Assignee: KYOCERA Tikitin Oy, Espoo (FI)

(21) Appl. No.: 18/002,391

(22) PCT Filed: Jul. 1, 2021
(86) PCT No.: PCT/FI2021/050506

§ 371 Date: Dec. 19, 2022

(30) Foreign Application Priority Data
Jul. 3, 2020 (FI) 20205711

(51) Int. Cl. H03H 9/24; H03H 3/007; H03H 9/02

(52) U.S. Cl. CPC H03H 9/2452; H03H 3/0072; H03H 9/02393

(57) ABSTRACT

A MEMS (microelectromechanical system) resonator includes a first layer of single-crystalline silicon, a second layer of single-crystalline silicon, and a piezoelectric layer in between said first layer of single-crystalline silicon and the second layer of single-crystalline silicon. A manufacturing method of the MEMS resonator includes at least one of the interfaces between the single-crystalline silicon layers and the piezoelectric layer be made by wafer bonding.

### FIELD

The aspects of the disclosed embodiments generally relate to microelectromechanical system, MEMS, resonators.

### BACKGROUND

This section illustrates useful background information without admission of any technique described herein representative of the state of the art.

Microelectromechanical system (MEMS) resonators are being developed to provide the same functionality as quartz resonators with benefits such as smaller chip size, reduced cost, and increased robustness against shock and vibrations.

A key performance parameter in MEMS resonators such as silicon MEMS resonators used for frequency reference applications is the equivalent series resistance (ESR). ESR is inversely proportional to the quality factor Q of the resonator, and thus the maximization of this parameter is often desirable. Other important features include low variation of the resonance frequency over the temperature range and good long-term stability (low ageing) of the resonance frequency.

### SUMMARY

The aspects of the disclosed embodiments are directed to provide an optimized MEMS resonator or at least to provide an alternative to existing technology.

According to a first example aspect of the disclosed embodiments there is provided a MEMS (microelectromechanical system) resonator, comprising:

a first layer of single-crystalline silicon,
a second layer of single-crystalline silicon, and
a piezoelectric layer in between said first layer of single-crystalline silicon and said second layer of single-crystalline silicon.

In certain embodiments, the first layer of single-crystalline silicon is an uppermost layer of the mentioned three layers and is used as an electrode for the MEMS resonator.

In certain embodiments, the MEMS resonator comprises the first layer of single-crystalline silicon as a top electrode and the second layer of single-crystalline silicon as a bottom electrode of the MEMS resonator.

In certain embodiments, the thickness of the first layer of single-crystalline silicon is in the range from 2 μm to 20 μm. In certain embodiments, the thickness of the second layer of single-crystalline silicon is in the range from 2 μm to 20 μm. In certain embodiments, the thickness of the piezoelectric layer is in the range from 0.3 μm to 5 μm. In certain embodiments, the first layer of single-crystalline silicon is of equal thickness and the second layer of single-crystalline silicon is of equal thickness (the thickness of the first and second layer may be the same or different depending on the embodiment).

In certain embodiments, an average impurity doping of either the first layer of single-crystalline silicon or the second layer of single-crystalline silicon or both the first layer and the second layer of single-crystalline silicon is 2*10¹⁹ cm⁻³ or more.

In certain embodiments, a <100> crystalline direction in the first layer of single-crystalline silicon is in a plane of the first layer of single-crystalline silicon (or deviates less than 10 degrees therefrom) and a <100> crystalline direction in the second layer of single-crystalline silicon is in a plane of the second layer of single-crystalline silicon (or deviates less than 10 degrees therefrom). The <100> crystalline direction that is in the plane of the first layer of single-crystalline silicon may be for example a [100] or a [010] direction. Similarly, the <100> crystalline direction that is in the plane of the second layer of single-crystalline silicon may be for example a [100] or a [010] direction.

In certain embodiments, a <100> crystalline direction in the first layer of single-crystalline silicon is parallel with (or deviates less than 10 degrees from) a <100> crystalline direction in the second layer of single-crystalline silicon.

Herein, the <100> crystalline direction in the first layer of single-crystalline silicon is in certain embodiments the same <100> crystalline direction as the <100> crystalline direction in the second layer of single-crystalline silicon. In other embodiments, the <100> crystalline direction in the first layer of single-crystalline silicon is a different <100> crystalline direction than the <100> crystalline direction in the second layer of single-crystalline silicon.

In certain embodiments, the crystalline directions in the first single-crystalline silicon layer and in the second single-crystalline silicon layer are parallel or deviate at most 10 degrees.

In certain embodiments, the temperature coefficient of the resonance frequency of either the first layer or the second layer of single-crystalline silicon layer is positive.

In certain embodiments, the crystalline c-axis of the piezoelectric layer is either parallel to the direction orthogonal to the wafer plane (or the plane defined by the piezoelectric layer) or at an angle larger than zero and smaller than 90 degrees with respect to the direction orthogonal to the wafer plane.

In certain embodiments, the resonance mode of the MEMS resonator is an in-plane resonance mode. In certain embodiments, the resonance mode of the MEMS resonator is a length-extensional resonance mode.

In certain embodiments, the resonance mode of the MEMS resonator is an in-plane resonance mode and the thickness of the first layer of single-crystalline silicon and the thickness of the second layer of single-crystalline silicon are equal within 20% or less.

In certain embodiments, the resonance mode of the MEMS resonator is an out-of-plane flexural mode and the thickness of the first layer of single-crystalline silicon substantially differs from the thickness of the second layer of single-crystalline silicon, for example, at least by 20% or at least by 50%.

In certain embodiments, the MEMS resonator comprises an elongated resonating element, such as a beam. In certain embodiments, the longitudinal direction of the elongated resonating element is parallel with (or deviates less than 10 degrees from) a <100> crystalline direction of the first layer of single-crystalline silicon, and the longitudinal direction of the elongated resonating element is parallel with (or deviates less than 10 degrees from) a <100> crystalline direction of the second layer of single-crystalline silicon.

In certain embodiments, the MEMS resonator comprises a resonating element in the form of a square. In certain embodiments, all sides of the square are parallel with (or deviate less than 10 degrees from) a <100> crystalline direction of the first layer of single-crystalline silicon, and all sides of the square are parallel with (or deviate less than 10 degrees from) a <100> crystalline direction of the second layer of single-crystalline silicon.

In certain embodiments, the MEMS resonator comprises a release trench surrounding the resonator and extending through all material layers of the resonator.

In certain embodiments, the resonator layout is of rectangular shape.

In certain embodiments, the MEMS resonator comprises an interconnection providing an electrical path to the second layer of single-crystalline silicon through an opening in the first layer of single-crystalline silicon and in the piezoelectric layer.

In certain embodiments, the MEMS resonator comprises an intermediate material layer between the first layer of single-crystalline silicon and the piezoelectric layer or between the second layer of single-crystalline silicon and the piezoelectric layer.

In certain embodiments, the intermediate material layer is for bonding a respective single-crystalline silicon layer and the piezoelectric layer.

In certain embodiments, there is an intermediate material layer both between the first layer of single-crystalline silicon and the piezoelectric layer and between the second layer of single-crystalline silicon and the piezoelectric layer.

In certain embodiments, the MEMS resonator comprises an additional material layer on a bottom surface of the second layer of single-crystalline silicon said additional material layer facing a cavity that separates the MEMS resonator from a substrate.

In certain embodiments, the MEMS resonator is mechanically suspended to an anchor region.

In certain embodiments, the MEMS resonator comprises a vertical trench extending (horizontally or laterally) from end to end of the first layer of single-crystalline silicon and vertically through the whole first layer of single-crystalline silicon said vertical trench electrically isolating two regions of the first layer of single-crystalline silicon.

In certain embodiments, the formed two regions function as two electrically isolated top electrodes.

In certain embodiments, the MEMS resonator comprises finetuning material layers on top of the first layer of single-crystalline silicon for resonator frequency trimming.

In certain embodiments, the MEMS resonator has reflection symmetry. In certain embodiments, the MEMS resonator has mirror symmetry. In certain embodiments, the mirror symmetry is with respect to x-axis and/or y-axis.

In certain embodiments, the MEMS resonator is fabricated on a silicon substrate or wafer. In certain embodiments, the MEMS resonator assembly is fabricated on a silicon-insulator-silicon substrate (or wafer, e.g., a silicon on insulator, SOI, wafer, or a cavity-SOI, C-SOI, wafer).

According to a second example aspect of the disclosed embodiments there is provided a method of manufacturing the MEMS resonator of any preceding claim, wherein at least one of the following interfaces:

an interface between the first layer of single-crystalline silicon and the piezoelectric layer; and

an interface between the second layer of single-crystalline silicon and the piezoelectric layer is made by wafer bonding.

In other words, at least one of the interfaces between the single-crystalline silicon layers and the piezoelectric layer is fabricated by a wafer bonding method.

Different non-binding example aspects and embodiments have been presented in the foregoing. The above embodiments and embodiments described later in this description are used to explain selected aspects or steps that may be utilized in implementations of the present disclosure. It should be appreciated that corresponding embodiments apply to other example aspects as well. Any appropriate combinations of the embodiments can be formed.

### BRIEF DESCRIPTION OF THE DRAWINGS

The aspects of the disclosed embodiments will now be described, by way of example only, with reference to the accompanying drawings, in which:

FIG. 1 shows a schematic cross-section of a MEMS resonator in accordance with certain embodiments;

FIG. 2 shows an example of a resonator layout of a MEMS resonator with a materials stack shown in FIG. 1;

FIG. 3 shows a schematic cross section of the MEMS resonator of FIG. 2 taken along section BB′;

FIGS. 4A-4E show manufacturing steps of MEMS resonators in accordance with certain embodiments;

FIG. 5 shows certain further alternatives to the materials stack of MEMS resonators in accordance with certain embodiments;

FIGS. 6A-6C show fabrication of a materials stack with an intermediate material layer in accordance with certain embodiments;

FIGS. 7A-7C show fabrication of a materials stack with an alternative intermediate material layer in accordance with certain embodiments;

FIG. 8 shows a schematic cross-section of a MEMS resonator in accordance with certain further embodiments;

FIGS. 9A and 9B show schematic cross-sections of MEMS resonators in accordance with yet further embodiments;

FIG. 10A shows a schematic cross-section of a MEMS resonator having two regions isolated by a trench in accordance with certain embodiments;

FIG. 10B shows an example of a resonator layout of the MEMS resonator shown in FIG. 10A;

FIG. 11A shows an example of a resonator layout of a length extensional mode MEMS resonator with a frequency-finetuning property in accordance with certain embodiments;

FIG. 11B shows a schematic cross-section of the MEMS resonator of FIG. 11A; and

FIG. 11C shows an example of a resonator layout of a MEMS resonator with adjacent sub-elements separated by elongated trenches in accordance with certain embodiments.

### DETAILED DESCRIPTION

In the following description, like numbers denote like elements.

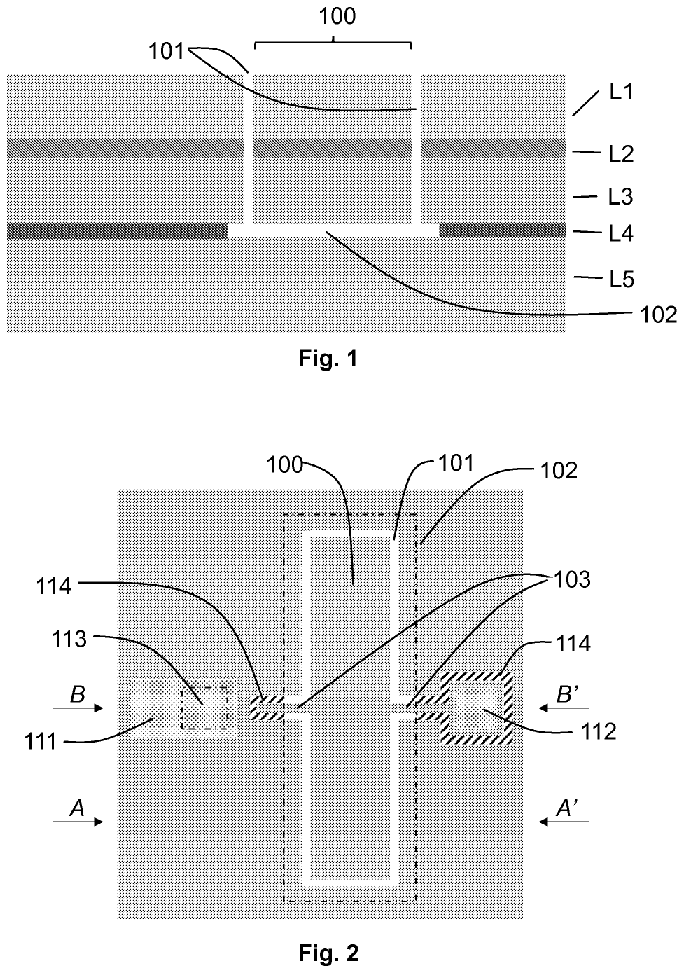

FIG. 1 shows a schematic cross-section of a MEMS (microelectromechanical system) resonator 100 in accordance with certain embodiments. The cross section of the MEMS resonator 100 comprises two single-crystalline layers of silicon L1, L3 with a layer of piezoelectric material L2 between the silicon layers. The piezoelectric material can be, e.g., AlN, Sc-doped AlN, ZnO, LiNbO₃, or LiTaO₃.

The MEMS resonator 100 is patterned in a stack of layers comprising the silicon layers L1, L3 and the piezoelectric layer L2 by a micromachining process which creates vertical trenches 101 through the materials layer stack. The lateral dimensions of the resonator 100 are defined by the vertical trench 101. There is a cavity 102 below the resonator which separates the resonator from a substrate L5. The substrate, or substrate wafer, L5 is typically a silicon wafer but it could also be made from another material. In typical embodiments, there is a layer of silicon oxide L4 between the substrate layer L5 and the lower silicon layer L3 forming the resonator in regions where there is no cavity. There are embodiments in which the layer L4 is from another material than silicon oxide, such as Al₂O₃, glass, or another insulating material.

In certain embodiments, the thickness of the upper silicon layer L1 is in the range of 2 μm to 40 μm, the thickness of the lower silicon layer L3 is in the range of 2 μm to 40 μm, and the thickness of the piezoelectric layer L2 is in the range of 200 nm to 8 μm. In certain embodiments, the thicknesses L1 and L3 are equal or substantially equal, and in certain embodiments, L1 and L3 differ significantly from each other, even by an order of magnitude.

In certain embodiments, the crystalline c-axis of the piezoelectric layer L2 is parallel to the direction orthogonal to the wafer plane or at an angle larger than zero and smaller than 90 degrees with respect to the direction orthogonal to the wafer plane. Tilting of the c-axis with respect to the direction orthogonal to the wafer plane can be used to improve electromechanical coupling of some mechanical resonance modes, such as in-plane Lame mode resonators.

FIG. 2 shows an example of the resonator layout with the materials stack shown in FIG. 1 (the cross section AA′ of FIG. 2 is illustrated in FIG. 1). The geometry of the resonator 100 is that of a length-extensional resonator with lateral dimensions defined by the vertical trench 101. The resonator is suspended by two beams 103 to a mechanically anchored region outside the cavity area 102. The dashed line 102 indicates the border line of the cavity 102 within the layer L4 between the substrate L5 and the lower silicon layer L3.

In other embodiments, the resonator has different geometries and different vibration modes such as tuning fork resonators vibrating either in-plane or out-of-plane, square-extensional mode or Lame-mode resonators, various spring-mass resonators with or without coupling elements vibrating in-plane or out-of-plane, various length-extensional resonators with coupling elements, and various beam-shaped resonators with or without coupling elements.

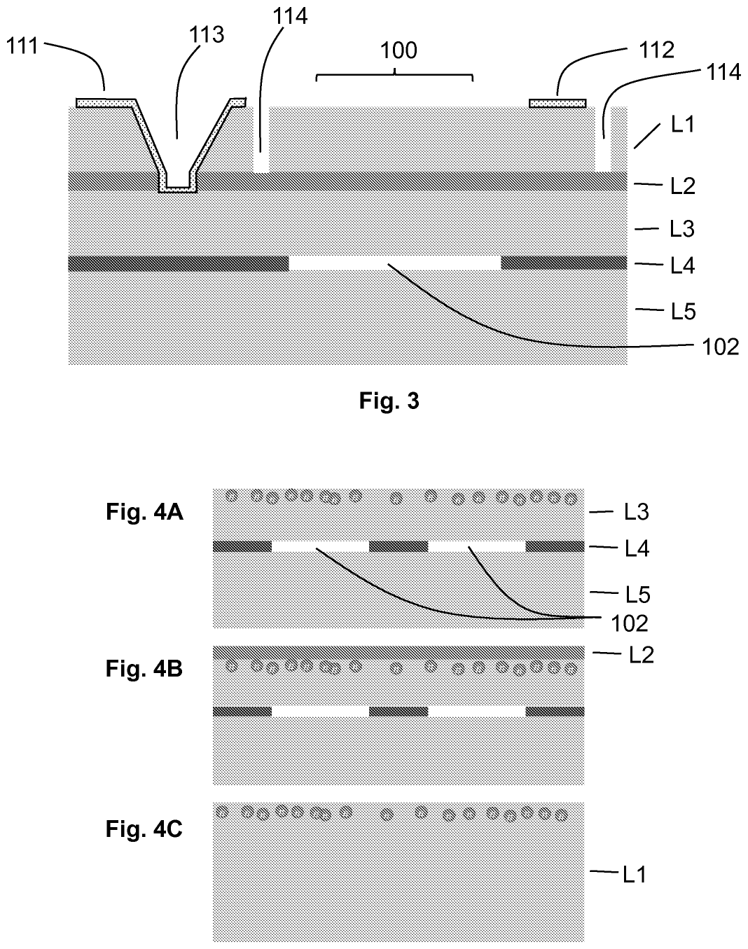

In typical embodiments, there are two electrical terminals with electrical interconnections 111 and 112, respectively. The electrical interconnections are typically made of thin metallic layers such as molybdenum, aluminum, or gold, or a stack of thin metallic layers. A cross section of the MEMS resonator along the section BB′ of FIG. 2 is presented in FIG. 3 to illustrate the structural details including the electrical interconnections 111, 112. A trench 114 penetrating through the layer L1 is provided to galvanically isolate the interconnections 111, 112 from each other. In other embodiments, the layout of the trench 114 optimized to minimize the capacitance between terminals 111 and 112 and thereby to maximize the figure of merit of the resonator. In typical embodiments, one of the interconnections (here: 111) provides an electrical path to the lower silicon layer L3 while the other interconnection (112) provides an electrical path to the resonator structure formed from the upper silicon layer L1. An opening 113 through the upper silicon layer L1 and the piezoelectric layer L2 is provided so that the metal deposited at the terminal 111 provides a galvanic contact to the layer L3.

In other embodiments, the layout of electrical terminals (111, 112) and the layout of the resonator 100 including the (release) trench 101, the cavity 102, and the (isolation) trench 114 differ from that shown in FIG. 2, and the number of electrical terminals of the resonator can be two, three, or more.

In the MEMS resonators according to certain embodiments of the present disclosure, single-crystalline layers L1 and L3 that are preferably of doped silicon are used as top and bottom electrodes, respectively. The use of (doped) single-crystalline silicon as electrode material is advantageous. There are very few structural imperfections in single-crystalline silicon and therefore the long-term stability of the resonance frequency does not suffer from dislocation effects (such as work hardening) in the electrode material whereas piezo-coupled MEMS resonators which use metallic thin films as electrodes may suffer from adverse effects related to dislocations.

In certain embodiments, the single crystalline silicon layers L1 and L3 are degenerately doped using phosphorus, arsenic, lithium, boron, or other dopants, or a combination of different dopants. More than 50% of the resonator mass consists of degenerately doped silicon, and/or the resonator comprises a body of silicon doped to an average impurity concentration of at least 210¹⁹ cm⁻³, such as at least 10²⁰ cm⁻³. The doping level in the layers L1 and L3 can be substantially same or different. The doping can be either homogeneous or inhomogeneous within the layers L1 and L3. Strong doping of silicon is useful for reducing the thermal dependency of the Young's modulus of silicon which in turn reduces temperature dependency of the resonance frequency of the MEMS resonator. In some embodiments, the temperature coefficient of the Young's modulus is positive for one or both of the layers L1 and L3. In particular, degenerate n-type phosphorous doping has been used to reduce the thermal dependence of MEMS resonators. There are several techniques available for strong phosphorous doping such as PSG-doping, POCl₃ doping, ion implantation, and use of phosphorous oxide (P₂O₅) doping wafers.

For optimization of the frequency vs. temperature characteristics of the MEMS resonator the resonator geometry has in certain embodiments a certain alignment with respect to the crystalline axes of the single-crystalline silicon which comprises most of the body of the resonator structure. In certain embodiments, the crystalline directions in the layers L1 and L3 of single-crystalline silicon are such that a <100> direction is in the plane of the respective layer. In certain embodiments, there are two <100> crystalline directions such as [100] and [010] in the plane of the layer L1 and/or L3. In certain embodiments, the layers L1 and L3 are aligned so that the crystalline axes of the L1 layer are essentially parallel to the respective crystalline axes of the layer L3 so that the deviations of the respective crystalline directions from each other are less than 10 degrees.

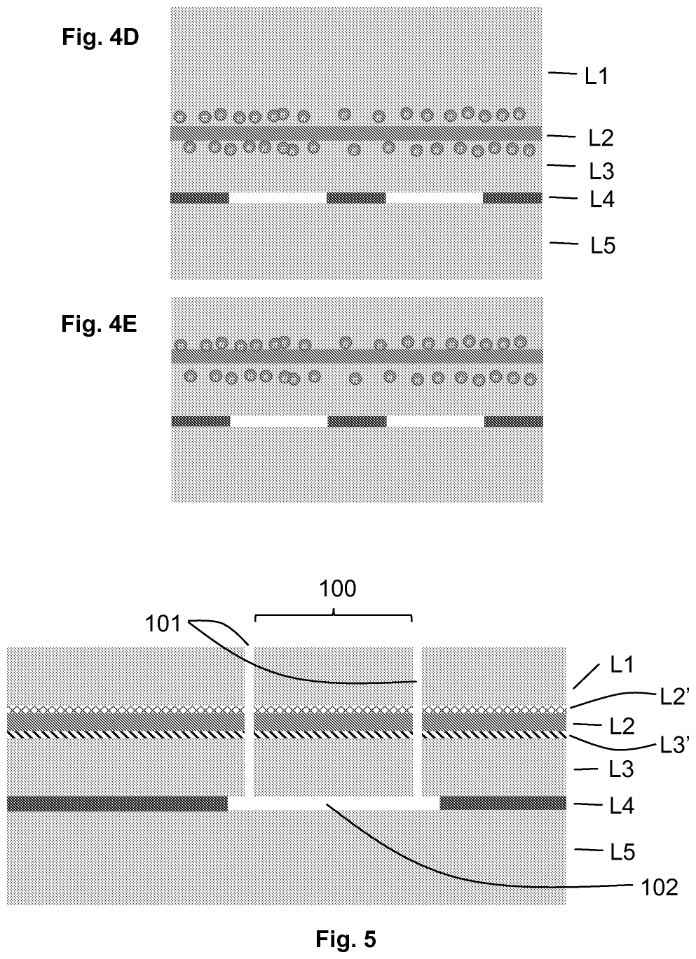

The main steps of the fabrication of the materials stack for MEMS resonators according to certain embodiments of the present disclosure are illustrated in FIGS. 4A-4E. In some embodiments, the starting point for MEMS processing is a cavity-SOI wafer illustrated in FIG. 4A in which the silicon layer above the cavity forms the single-crystalline silicon layer L3. In certain embodiments, the concentration of phosphorous in the single-crystalline silicon layer L3 is increased by additional doping, as schematically illustrated in FIG. 4A. After doping, a piezoelectric layer L2 such as AlN or Sc-doped AlN or another piezoelectric material, is deposited on the cavity-SOI wafer as illustrated in FIG. 4B.

In certain embodiments, the upper single-crystalline layer L1 of the materials stack according to the present disclosure, is formed from another silicon wafer, illustrated in FIG. 4C. In some embodiments, to improve the electrical conductivity and/or to reduce the temperature dependency of the resonance frequency, one surface of the silicon wafer L1 is doped, for example with phosphorous. The doped surface of the wafer L1 is bonded to the cavity-SOI wafer containing the piezoelectric layer L2, to result in the materials stack illustrated in FIG. 4D. The thickness of the silicon layer L1 is then grinded down to the desired thickness, as illustrated in FIG. 4E.

Further embodiments to the resonator materials stack are illustrated in FIG. 5. In some embodiments, an intermediate materials layer L3′ between the silicon layer L3 and the piezoelectric layer L2 is provided. In some embodiments, an intermediate materials layer L2′ between the silicon layer L1 and the piezoelectric layer L2 is provided.

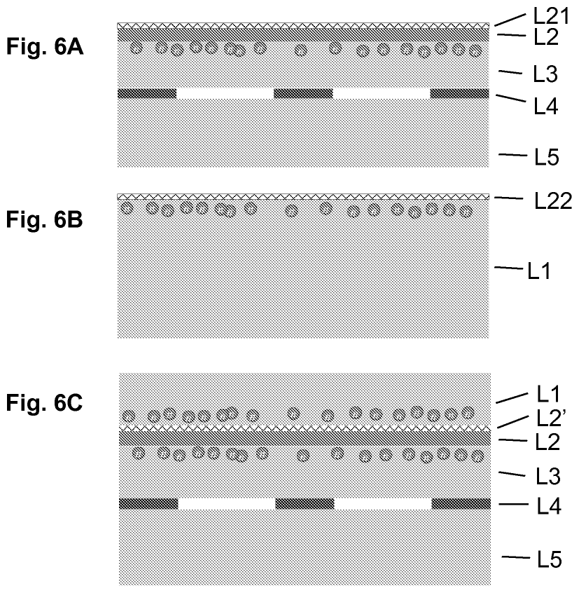

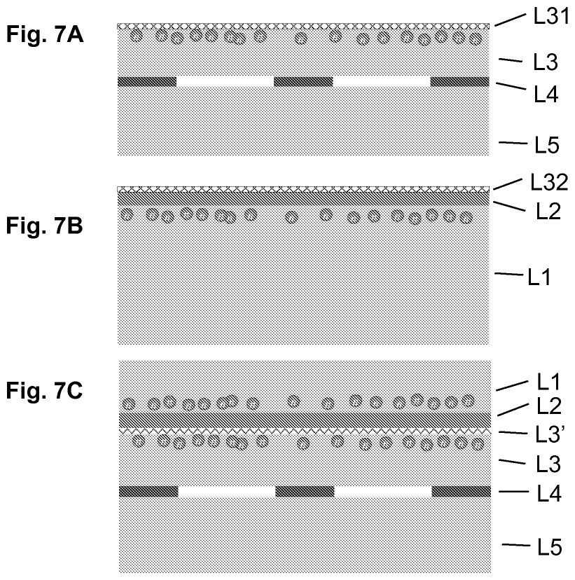

The layer L2′ may be used to bond the silicon layer L1 to the piezoelectric layer L2. There are several alternative materials for forming the layer L2′ such as silicon oxide, polycrystalline silicon, metals (such as gold, aluminum, molybdenum, copper, and silver), intermetallic compounds (such as Cu₃Sn and Cu₆Sn₅), high-dielectric materials such as Al₂O₃, Hf₂O, TiO₂, Mo—Au nanolaminate, and polymer adhesive materials. These alternative materials forming the layer L2′ can be used to build the materials stack according to embodiments of the present disclosure by using wafer bonding (to be discussed below in more detail in context with FIGS. 6A-6C and FIGS. 7A-7C).

Use of an intermediate materials layer L2′ between the layers L1 and L2 to facilitate wafer bonding is further illustrated in an exemplary embodiment of FIGS. 6A-6C which exploits Al₂O₃ in the layer L2′ for wafer bonding. The layer L21 of Al₂O₃ is deposited on the piezoelectric layer L2 on the cavity-SOI wafer (FIG. 6A), and the layer L22 of Al₂O₃ is deposited on the doped silicon wafer (FIG. 6B), and these wafers are bonded together and grinded down to the final thickness to result in the wafer used to fabricate the resonator according to the present disclosure (FIG. 6C). The materials layers L21 and L22 form together the layer L2″ of Al₂O₃ after the wafer bonding step.

There are several alternative process flows for creating the materials stack shown in embodiments of the present disclosure. To further illuminate this point, FIGS. 7A-C illustrate one alternative. In this case, the piezoelectric layer L2 is deposited on the silicon wafer containing the upper silicon layer L1 (illustrated in FIG. 7B) rather than on the cavity-SOI wafer (illustrated in FIG. 7A). Bonding of the two wafers is facilitated by deposition of the layer L31 of Al₂O₃ on the cavity-SOI wafer (see FIG. 7A) and the layer L32 of Al₂O₃ on the doped silicon wafer with the piezoelectric layer L2 (see FIG. 7B). These two wafers are then bonded and grinded down to the final thickness to result in the materials stack illustrated in FIG. 7C with the materials layer L3′ consisting of the Al₂O₃ layers L31 and L32. In further alternative process flows, the intermediate materials layer L3′ used for bonding may be selected from the group of materials consisting of silicon oxide, polycrystalline silicon, metals (such as gold, aluminum, molybdenum, copper, and silver), intermetallic compounds (such as Cu₃Sn and Cu₆Sn₅), other high-dielectric materials such as Hf₂O or TiO₂, Mo—Au nanolaminate, and polymer adhesive materials.

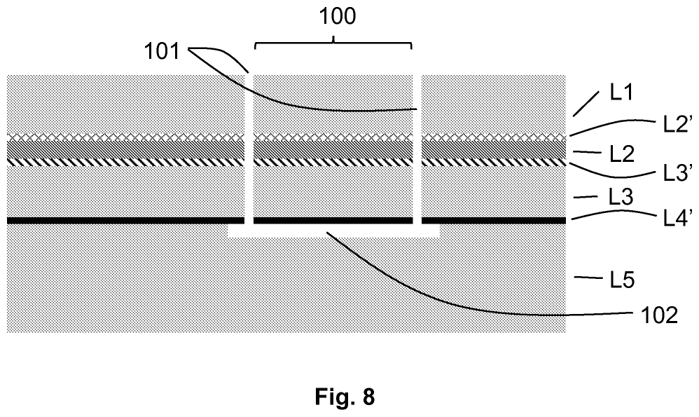

In some embodiments, there is a materials layer L4′ on the bottom surface of the lower Si layer L3 facing the cavity 102 as illustrated in FIG. 8. The layer L4′ may be of silicon oxide. The silicon oxide layer may be used to reduce the thermal dependency of the Young's modulus of the resonator materials stack and thereby to reduce the temperature dependency of the resonance frequency of the MEMS resonator. As discussed above, there may be a silicon oxide layer also within the intermediate layers L3′ and L2′ and, in yet other embodiments, on top of the layer L1.

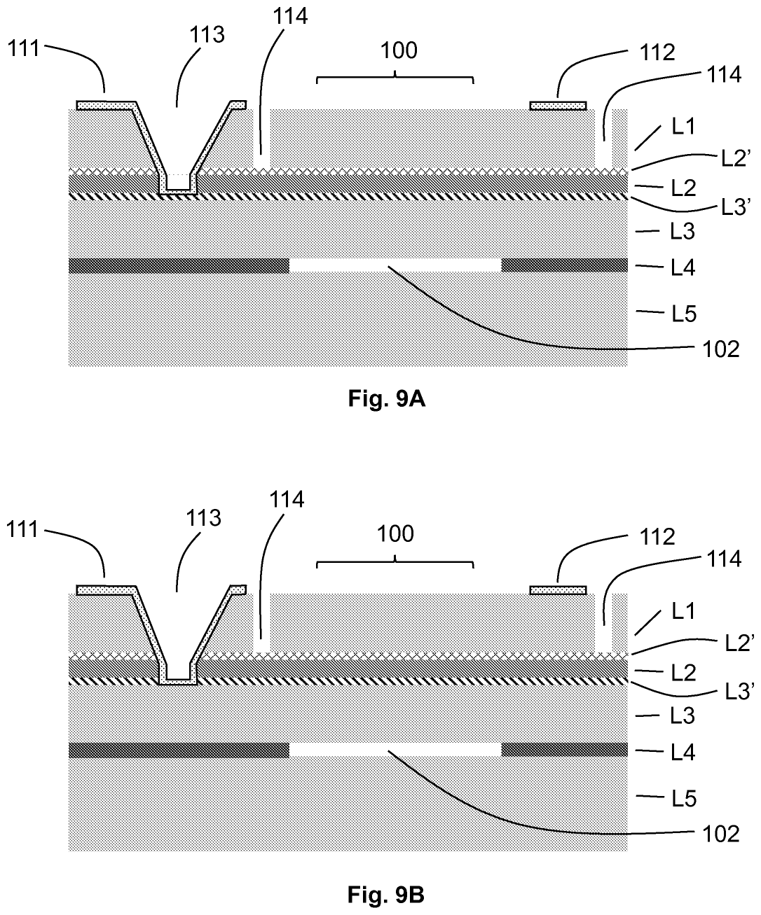

In some embodiments, the layer L3′ comprises electrically conducting material such as molybdenum, optionally with thin adhesion layers between the conducting material (such as Mo) and the silicon layer L3. In such embodiments, the electrically conducting material in the L3′ layer can serve as the bottom electrode. To create a galvanic contact to the bottom electrode in such a resonator, the electrical interconnection 111 to the bottom electrode needs to extend only to the electrically conducting L3′ layer as illustrated in FIG. 9A.

In further embodiments, there are resonators with an intermediate materials layer L3′ (between the layers L2 and L3) made of electrically isolating material such as Al₂O₃. If the layer L3 of such a resonator is used as a galvanically connected electrode, the opening 113 extends through the layer L3′ in order to provide an electrical interconnection 111 for the layer L3, as illustrated in FIG. 9B.

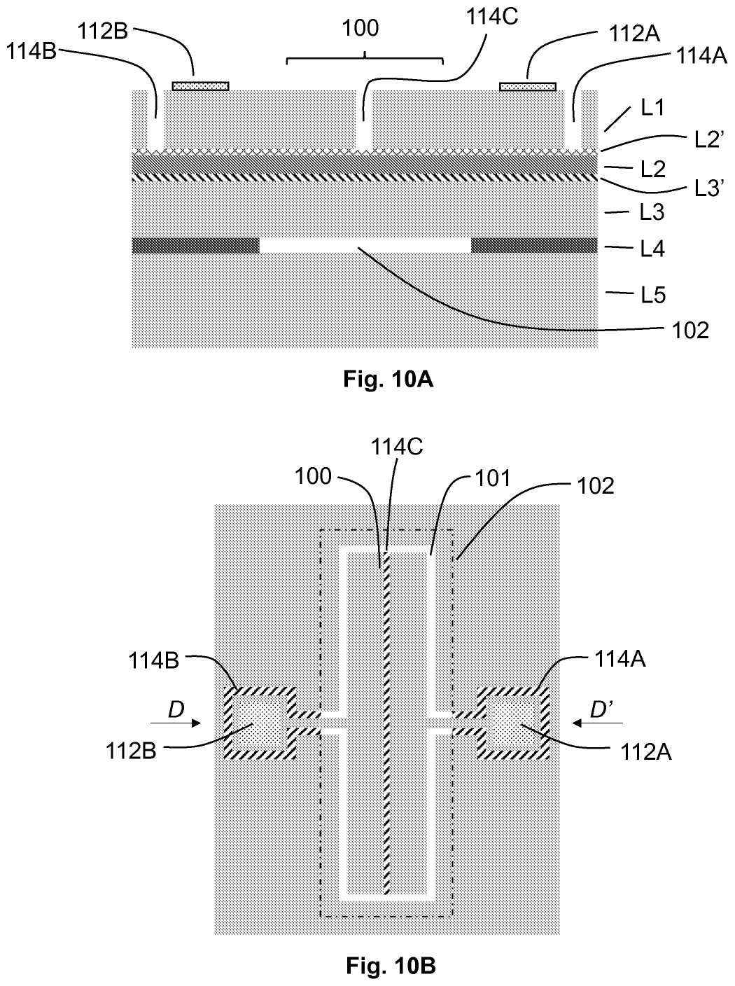

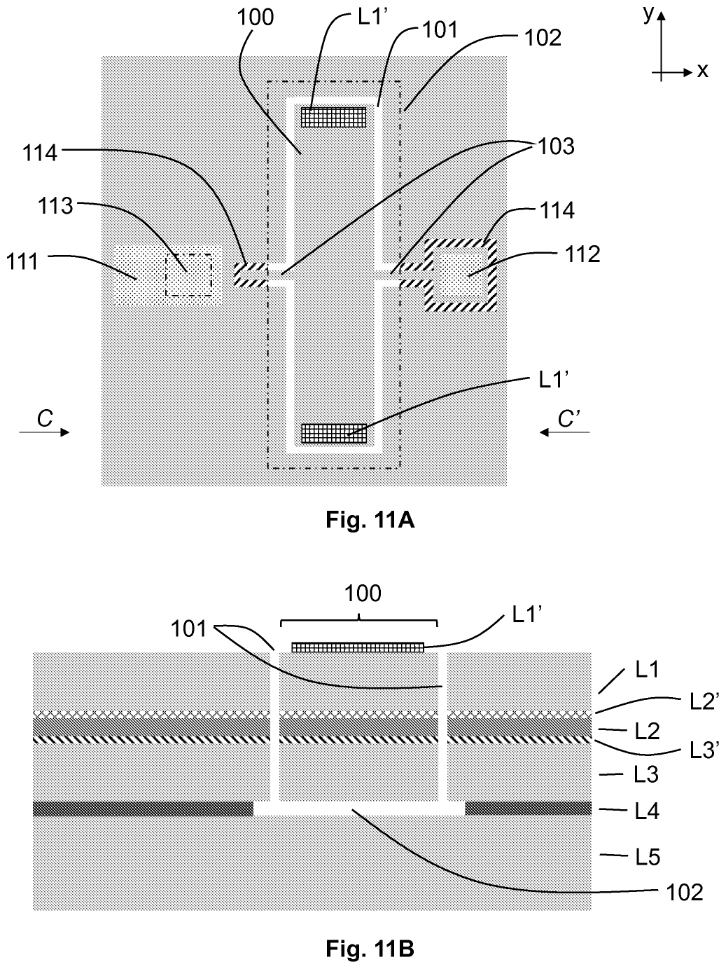

In further embodiments, there are provided resonators in which the layer L1 comprises of two regions which are electrically isolated from each other and which are part of the resonator 100 structure. A cross section of such a resonator with two top electrodes is illustrated in FIG. 10A and the corresponding top view is presented in FIG. 10B (FIG. 10A corresponds to the cross section DD′ of FIG. 10B). The top electrodes 112A and 112B have been patterned in the layer L1 by vertical trenches 114A, 114B, and 114C which extend through the electrically conducting layers above the piezoelectric layer L2 (in the embodiment illustrated in FIG. 10A it is assumed that the layer L2′ is electrically isolating so that the isolation trench needs only to penetrate through the layer L1) and by the vertical trench 110 which extends to the cavity 102 below the resonator 100. In the embodiment illustrated in FIGS. 10A-10B, the bottom electrode (the layer L3 and/or L3′) is electrically floating. In further embodiments, there are resonators with two (or more) top electrodes and a galvanically connected bottom electrode.

In some embodiments, there is a materials layer L1′ on the top surface of the resonator for finetuning the resonance frequency of the resonator. It is advantageous to pattern the materials layer L1′ so that it covers mainly only those areas of the resonator which do not experience much strain during the vibration so that the contribution of the L1′ patterns to the spring constant of the resonator remains vanishingly small. This brings certain advantages. First, structural ageing effects in the materials layer L1′ (such as movements of lattice dislocations) have minimal contribution to the long-term drift of the resonance frequency. Second, the contribution of the L1′ materials layer to the overall temperature coefficient of the resonance frequency remains very small which facilitates design of resonators with zero temperature coefficient. Third, it is possible to trim the frequency of the resonator by removing the surface layer of the resonator for example by ion beam trimming.

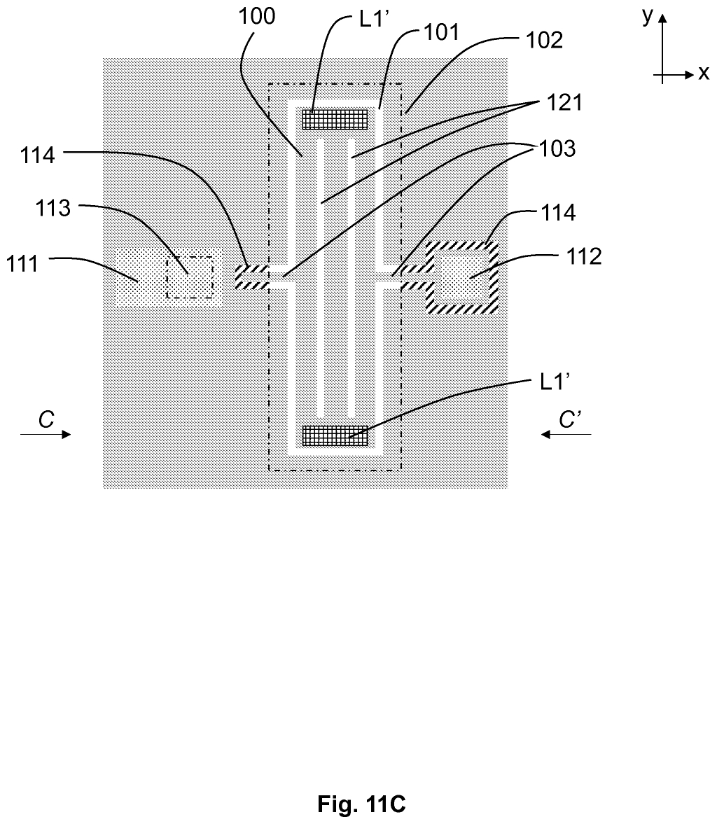

In the case of a length-extensional resonator illustrated in FIG. 11A, patterns of the materials layer L1′ are preferably symmetrically deposited on the distal areas of the top surface of the (beam) resonator. The material portions with the L1′ layer do not experience much strain while the resonator vibrates and the main effect of the deposited L1′ patterns is to contribute to the mass of the resonator (without affecting the spring constant) and thereby to change the resonance frequency. Cross section of the materials stack of the resonator illustrated in FIG. 11A is presented in FIG. 11B along the cross section CC′ containing the materials layer L1′. To facilitate large frequency tuning with a thin materials layer (for example, by ion beam trimming) it is advantageous if the materials layer L1′ comprises a heavy material such as gold. The thickness of the layer L1′ can be in the range from 20 nm to 1000 nm, such as from 50 nm to 300 nm.

In some embodiments, the materials layer L1′ covers substantially the whole top surface of the resonator including also areas which experience high strain during the vibration. In such a case, the long-term stability of the elastic properties of the resonator is not optimal but the high quality factor (and thereby the low ESR) remains an advantage, brought by the materials stack of the resonator according to embodiments of the present disclosure. In addition, the frequency of the MEMS resonator can be tuned by trimming the thickness of the L1′ layer for example by ion beam trimming.

In further embodiments, the MEMS resonator may take the form of a length-extensional resonator assembly comprising adjacent length-extensional resonator elements, connected at non-nodal positions by connection elements and separated by elongated trenches. Such a length-extensional resonator assembly is illustrated in FIG. 11C. Adjacent length-extensional resonator elements are separated by vertical trenches 121 which penetrate through all the materials layers of the MEMS resonator 100, similarly to the vertical trenches 101 which define the overall lateral shape of the resonator 100.

In yet further embodiments, the resonator takes the form of an out-of-plane-mode resonator (vibrating in the z-direction) such as a flexural beam resonator, a flexural plate resonator, or a resonator assembly consisting of or comprising connected out-of-plane flexural beams and/or plate elements and/or proof masses. A common feature between such out-of-plane resonators is that the neutral plane for out-of-plane bending is either below or above the piezoelectric layer L2. This is achieved when the thicknesses of the single-crystalline silicon layers L1 and L3 differ substantially from each other, such as 50% or more. In such a case, application of an electric field across the piezoelectric layer causes a strain field in the materials stack which results in out-of-plane bending.

In case of in-plane resonators according to embodiments of the present disclosure, such as length-extensional resonators, length-extensional resonator assemblies, square-extensional resonators, or various spring-mass resonators, it is advantageous that the neutral plane for out-of-plane bending is within the piezoelectric layer L2. This is achieved when the thicknesses of the single-crystalline silicon layers L1 and L3 are equal or almost equal, such as equal within 20% or less. In such a case, the application of an electric field across the piezoelectric layer supports only in-plane motion. Therefore, out-of-plane parasitic resonance modes are suppressed and the quality factor (Q) of the desired in-plane resonance mode is increased.

Without limiting the scope and interpretation of the patent claims, certain technical effects of one or more of the example embodiments disclosed herein are listed in the following. A technical effect is good long-term frequency stability. A further technical effect is a low equivalent series resistance (ESR) and a high quality factor (Q). A further technical effect is absence of parasitic resonances.

The foregoing description has provided by way of non-limiting examples of particular implementations and embodiments of the present disclosure a full and informative description of the best mode presently contemplated by the inventors for carrying out the present disclosure. It is however clear to a person skilled in the art that the present disclosure is not restricted to details of the embodiments presented above, but that it can be implemented in other embodiments using equivalent means without deviating from the characteristics of the present disclosure.

Furthermore, some of the features of the above-disclosed embodiments may be used to advantage without the corresponding use of other features. As such, the foregoing description should be considered as merely illustrative of the principles of the present disclosure, and not in limitation thereof. Hence, the scope of the aspects of the disclosed embodiments are only restricted by the appended patent claims.

1. A MEMS (microelectromechanical system) resonator, comprising:
a first layer of single-crystalline silicon;
a second layer of single-crystalline silicon; and
a piezoelectric layer in between said first layer of single-crystalline silicon and said second layer of single-crystalline silicon.

2. The MEMS resonator of claim 1, wherein the first layer of single-crystalline silicon is an uppermost layer of the mentioned three layers and is used as an electrode for the MEMS resonator.

3. The MEMS resonator of claim 1, wherein an average impurity doping of either the first layer of single-crystalline silicon or the second layer of single-crystalline silicon or both the first layer and the second layer of single-crystalline silicon is 2*10¹⁹ cm⁻³ or more.

4. The MEMS resonator of claim 1, wherein a <100> crystalline direction in the first layer of single-crystalline silicon is in a plane of the first layer of single-crystalline silicon, or deviates less than 10 degrees therefrom, and a <100> crystalline direction in the second layer of single-crystalline silicon is in a plane of the second layer (L3) of single-crystalline silicon, or deviates less than 10 degrees therefrom.

5. The MEMS resonator of claim 1, wherein a <100> crystalline direction in the first layer of single-crystalline silicon is parallel with, or deviates less than 10 degrees from, a <100> crystalline direction in the second layer of single-crystalline silicon.

6. The MEMS resonator of claim 1, wherein the crystalline directions in the first single-crystalline silicon layer and in the second single-crystalline silicon layer are parallel or deviate at most 10 degrees.

7. The MEMS resonator of claim 1, wherein the temperature coefficient of the resonance frequency of either the first layer or the second layer of single-crystalline silicon layer is positive.

8. The MEMS resonator of claim 1, wherein the crystalline c-axis of the piezoelectric layer is either parallel to the direction orthogonal to the plane defined by the piezoelectric layer or at an angle larger than zero and smaller than 90 degrees with respect to the direction orthogonal to said plane.

9. The MEMS resonator of claim 1, wherein the resonance mode of the MEMS resonator is an in-plane resonance mode and the thickness of the first layer of single-crystalline silicon and the thickness of the second layer of single-crystalline silicon are equal within 20% or less.

10. The MEMS resonator of claim 1, wherein the resonance mode of the MEMS resonator is a length-extensional mode resonance.

11. The MEMS resonator of claim 1, wherein the resonance mode of the MEMS resonator is an out-of-plane flexural mode and the thickness of the first layer of single-crystalline silicon substantially differs from the thickness of the second layer of single-crystalline silicon, for example, at least by 20% or at least by 50%.

12. The MEMS resonator of claim 1, comprising a release trench surrounding the resonator and extending through all material layers of the resonator.

13. The MEMS resonator of claim 1, comprising an interconnection providing an electrical path to the second layer of single-crystalline silicon through an opening in the first layer of single-crystalline silicon and in the piezoelectric layer.

14. The MEMS resonator of claim 1, comprising an intermediate material layer between the first layer of single-crystalline silicon and the piezoelectric layer or between the second layer of single-crystalline silicon and the piezoelectric layer.

15. The MEMS resonator of claim 1, comprising an additional material layer on a bottom surface of the second layer of single-crystalline silicon said additional material layer facing a cavity that separates the MEMS resonator from a substrate.

16. The MEMS resonator of claim 1, comprising a vertical trench extending from end to end of the first layer of single-crystalline silicon and vertically through the whole first layer of single-crystalline silicon said vertical trench electrically isolating two regions of the first layer of single-crystalline silicon.

17. The MEMS resonator of claim 1, comprising finetuning material layers on top of the first layer of single-crystalline silicon for resonance frequency trimming.

18. A method of manufacturing the MEMS resonator of claim 1, wherein at least one of the following interfaces:
an interface between the first layer of single-crystalline silicon and the piezoelectric layer; and
an interface between the second layer of single-crystalline silicon and the piezoelectric layer
is made by wafer bonding.
